(19) United States
(12) Patent Application Publication
(10) Pub. No.: US 2007/0040159 A1
(43) Pub. Date: Feb. 22, 2007

(54) Manufacturing method and structure for improving the characteristics of phase change memory

(76) Inventor: Wen-Han Wang, Hsin Chu city (TW)

Correspondence Address: RABIN & BERDO, P.C., Suite 500, 1101 14 Street, N.W., Washington, DC, 20005, US

(21) Appl. No.: 11/357,150

(22) Filed: Feb. 21, 2006

(30) Foreign Application Priority Data
Aug. 19, 2005 (TW) 94128535

(51) Int. Cl. H01L 29/04

(52) U.S. Cl. 257/3

(57) ABSTRACT

A manufacturing method and structure for better phase change memory characteristics by improving the interface and the hole-filling properties. The present invention can reduce the power consumption needed to operate and is easy to fabricate.

### BACKGROUND OF THE INVENTION

1. Field of the Invention

The present invention relates to a manufacturing method and structure for improving the characteristics of phase change memory.

2. Description of Related Art

Energy Conversion Devices Inc. proposed ovonic unified memory (OUM) theory in the 1960s. Energy Conversion Devices Inc. discovered optic properties and a conductance ratio difference in phase change memory between its generally amorphous and generally crystalline states. Because Phase change materials have the characteristic of being able to switch between two phases rapidly it has two functions—firstly, it is able to act as a switch and secondly, it can act as a memory. Phase change memory uses chalcogenides (a kind of conductive glass) as the core material for phase change memory and needs to be connected to an electrode. Phase change memory can switch between the amorphous and crystalline states using different current pulses. The amorphous and crystalline states of the phase change material are maintained when the pulse is over. Phase change memory has the characteristics of large sensing signal, high density, high endurance, fast access speed, and low current/power consumption. Phase change memory has the potential to perform better than other non-volatile memories. Phase change memory is suitable for portable electronic products with its small size.

The manufacturing method for phase change memory and the related art for reducing the contact area of the phase change memory electrode overcome the power consumption problems disclosed in prior patent documents. To achieve a reduced contact area size of the phase change memory, several methods have been disclosed. The first method was published in U.S. Pat. No. 6,545,287 “Using selective deposition to form phase-change memory cells” and in U.S. Pat. No. 6,744,088 “Phase change memory device on a planar composite layer”, provided by Intel Corporation. U.S. Pat. No. 6,635,951 “Small electrode for chalcogenide memories” provided by Micron further disclosed a manufacturing process for generating a spacer to reduce the contact area by increasing the angle with etching and chemical mechanical polishing (CMP) process. FIG. 1 shows a schematic depiction to form phase-change memory cells. The method for manufacturing this phase change memory in U.S. Pat. No. 6,545,287 patent deposits the phase change layer 10 into the via. However, the phase change material is not suitable for bending because gaps may be formed during the deposition process and may affect the operation characteristics.

Currently, phase change material can only be deposited using physical vapor deposition (PVD) process. However, PVD is not suitable for small via and it also limits the application of this structure.

HP provided the second method in U.S. Pat. No. 6,746,892 “Low heat loss and small contact area composition electrode for a phase change media memory device.” This was expanded upon in US Pat. No. USRE 37,259 “Multibit single cell memory element having tapered contact” provided by Energy conversion devices, Inc. disclosed a manufacturing process for generating tapered point lower electrode to reduce the electrode contact area of phase change memory by repeating the adjustable etching process. The manufacturing method includes complex problems like exposure issues and etching issues.

A third method was provided by Ovonyx Inc. in U.S. Pat. No. 6,646,297 “Lower electrode isolation in a double-wide trench” and U.S. Pat. No. 6,437,383 “Dual trench isolation for a phase change memory cell and method of making same” provided by Intel Corporation which discloses a manufacturing process for making trenches/sidewall lower electrodes to reduce the contact area of phase change memory by increasing the size of the trenches via etching and an adjustable sidewall height process. The sidewall areas may not the same each time. When a sidewall is being made, only one side of the sidewall can be used. The disadvantage of this method is that it will take more area to fabricate the device.

A fourth method was provided by Samsung Electronics Co., Ltd. By using the thickness of a horizontal electrode film to reduce the contact area. The disadvantage of the method is it is difficult to control the alignment and etching process and the lateral electrode may need more area to fabricate the device. FIG. 2 shows a schematic depiction of phase change memory cell in the prior art. A heat region of the phase change memory is centered in the bottom of the phase change layer 10.

### SUMMARY OF THE INVENTION

The main object of the present invention is to provide a manufacturing method and structure for improving the characteristics of phase change memory using current semiconductor manufacturing process. The method of the present invention can reduce the contact area and maintain stable component characteristics using simple manufacturing process.

To achieve the targets above, the present invention provides a manufacturing method for improving the characteristics of phase change memory comprising of providing a substrate; forming a bottom electronic pattern on said substrate; forming a layer of phase change material pattern on said bottom electronic pattern; forming a dielectric layer pattern on said layer of phase change material pattern; forming a spacer structure between an opening of said dielectric layer pattern; and depositing a top electrode pattern on said dielectric layer pattern.

The present invention further provides a structure for improving the characteristics of phase change memory comprising a substrate; a bottom electrode pattern formed on said substrate; a layer of phase change material pattern formed on said bottom electrode pattern; a dielectric layer pattern formed on said layer of phase change material pattern; a spacer structure formed between an opening of said dielectric layer pattern; and a top electrode pattern disposed upon said dielectric layer pattern.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a schematic depiction of the selective deposition being used to form phase-change memory cells in accordance with the prior art;

FIG. 2 is a schematic depiction of the phase change memory cells in accordance with the prior art;

FIG. 3 is a schematic depiction of a process of the bottom electrode pattern in accordance with an embodiment of the present invention;

FIG. 4 is a schematic depiction of a process of the phase change layer pattern in accordance with an embodiment of the present invention;

FIG. 5 is a schematic depiction of a process of the dielectric layer pattern in accordance with an embodiment of the present invention;

FIG. 6 is a schematic depiction of a process of the etching region in accordance with an embodiment of the present invention;

FIG. 7 is a schematic depiction of a process showing the deposition of another dielectric layer pattern in accordance with an embodiment of the present invention;

FIG. 8 is a schematic depiction of a process of the spacer structure in accordance with an embodiment of the present invention;

FIG. 9 is a schematic depiction of a process of the upper electrode pattern in accordance with an embodiment of the present invention; and

FIG. 10 is schematic depiction of a process of the phase change layer pattern of another embodiment of the present invention.

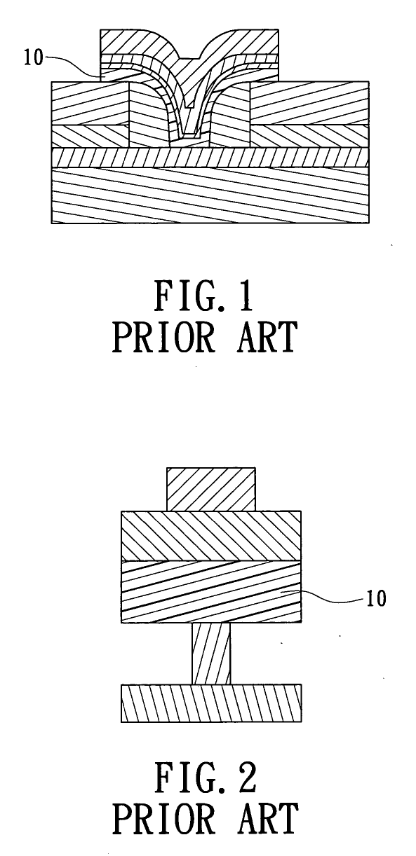

### DETAILED DESCRIPTION OF PREFERRED EMBODIMENTS

The present invention provides a simple manufacturing method for improving the characteristics of phase change memory. The method maintains a small contact area to reduce power consumption.

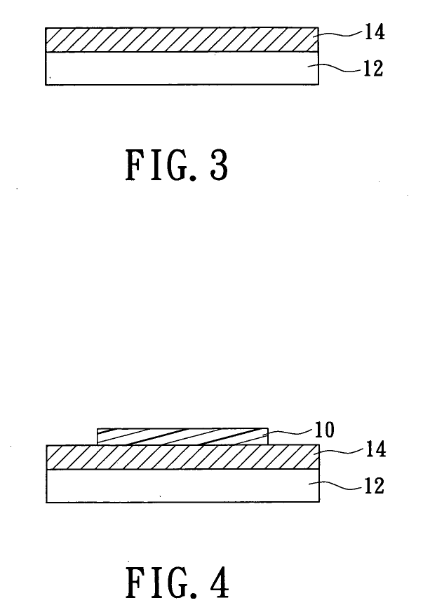

Please refer to FIG. 3, which is a process schematic depiction of the bottom electrode pattern in accordance with an embodiment of the present invention. A bottom electrode pattern 14 is formed on a substrate 12. The substrate 12 could be connected to CMOS, BJT or other driving devices.

FIG. 4 shows a schematic depiction of a process of the phase change layer pattern in accordance with an embodiment of the present invention. A layer of phase change material pattern 10 is formed on said bottom electrode pattern 14. In another embodiment at least one adhesive layer, at least one heating layer, or at least one etching stop layer is added on any side of the phase change material pattern 10 such that the etching is opened, the metal becomes adhesive, or heating efficiency is increased. The small contact area and heat region sits on the upper region of phase change material pattern 10.

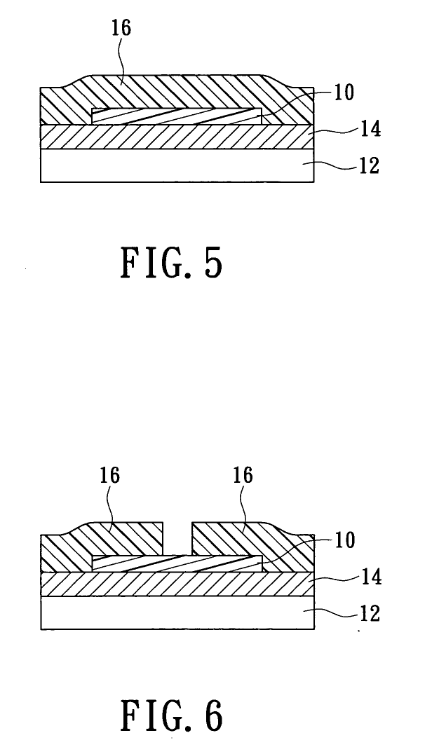

FIG. 5 shows a schematic depiction of a process of the dielectric layer pattern in accordance with an embodiment of the present invention. A dielectric layer pattern 16 is formed on the phase change material pattern 10 and the bottom electrode pattern 14.

FIG. 6 is a schematic depiction of a process of the etching region in accordance with an embodiment of the present invention. A region of dielectric layer pattern 16 is etched using etching technology.

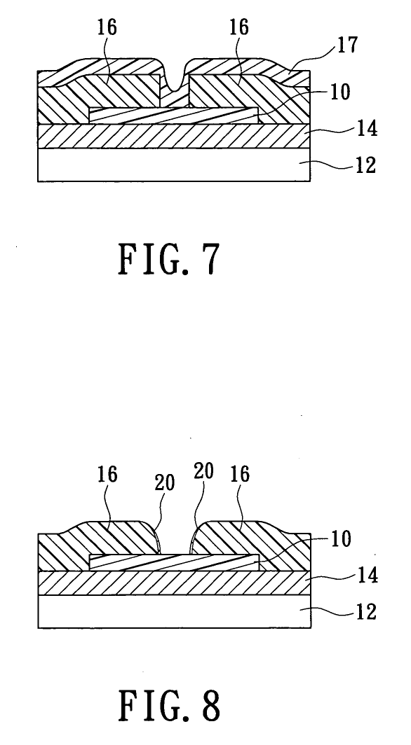

FIG. 7 is a schematic depiction of a process of covering another dielectric layer pattern in accordance with an embodiment of the present invention. A layer of another dielectric layer pattern 17 is deposited on the dielectric layer pattern 16.

FIG. 8 is a schematic depiction of a process of the spacer structure in accordance with an embodiment of the present invention. A spacer 20 is formed using isotropic etching on the dielectric layer pattern 17 to define the size of the contact area.

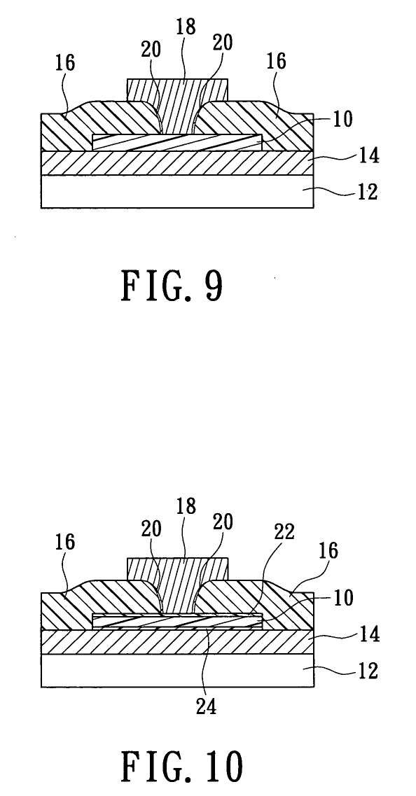

FIG. 9 is a schematic depiction of a process of the upper electrode pattern in accordance with an embodiment of the present invention. A top electrode pattern 18 is deposited on the dielectric layer pattern 16 and the opening defined by spacer 20. The phase change material 10 and top electrode layer 18 has a so called inverted T-shape structure. The spacer 20 has a metal tapered point that reduces the contact area. The deposition step may use a chemical vapor deposition (CVD) or physical vapor deposition (PVD) process.

FIG. 10 is schematic depiction of a process s of the phase change layer pattern according to another embodiment of the present invention. At least one etching stop layer (or at least one adhesive layer, or at least one heating layer) 22, 24 is formed on any side of the phase change material pattern 10. The at least one etching stop layer 22, 24 (or the least one adhesive layer, or the least one heating layer) protects the phase change layer pattern 10 from etching, increases adhesiveness between different materials, or increases heating efficiency when a pulse is forced into the device.

The layer of phase change material of the present invention is below the heating layer pattern and is different to the prior art. The present invention structure has several advantages. First, it reduces the contact area therefore reduces the power needed to operate the device. Second, it improves the interface characteristics between the phase change material and the electrode material by adding an adhesive layer, a heating layer, or an etching stop layer between the phase change material and the electrode material. Third, the metal chemical vapor deposition process replaces the phase change physical vapor deposition process.

The heating metal of the conventional structure is under the phase change material. However, the present invention reverses the convention structure such that the reduced contact area between the metal and the phase change material is in the upper region of the phase change material. The present invention maintains the smoothness of the phase change material. Metal CVD process has a better ability to fill in smaller via than PVD process using for phase change materials. The hole-filling ability can be increased by modifying the thickness of dielectric layer and spacer material.

To reduce the contact area between phase change material and the heating electrode, the present invention uses a spacer process, a photo-shifting process or other processes to achieve the effect. To increase the adhesiveness and heating efficiency, the present invention adds a heating layer between the phase change material and the electrode to improve the cell's characteristics.

It is to be understood, however, that even though numerous characteristics and advantages of the present invention have been set forth in the foregoing description, together with details of the structure and function of the invention, the disclosure is a illustration only, and changes may be made in detail, especially in matters of shape, size, and arrangement of parts within the principles of the invention to the full extent indicated by the broad general meaning of the terms in which the appended claims are expressed.

What is claimed is:

1. A manufacturing method for improving the characteristics of phase change memory, comprising the following steps:
providing a substrate;
forming a bottom electronic pattern on said substrate;
forming a layer of phase change material pattern on said bottom electronic pattern;
forming a dielectric layer pattern on said layer of phase change material pattern;
forming a spacer structure between an opening of said dielectric layer pattern; and
depositing a top electrode pattern on said dielectric layer pattern.

2. The method as claimed in claim 1, further comprising adding at least one adhesive layer, at least one heating layer, or at least one etching stop layer on any side of the layer of said phase change material pattern.

3. The method as claimed in claim 1, wherein the layer of phase change material pattern is a horizontal film.

4. The method as claimed in claim 1, wherein the spacer structure is formed by performing the etching process twice.

5. The method as claimed in claim 1, wherein the top electrode pattern is formed by a chemical vapor deposition (CVD).

6. The method as claimed in claim 1, wherein the layer of phase change material pattern and the top electrode pattern in the via part form an inverted T-shape structure.

7. A structure for improving the characteristics of phase change memory, comprising the following steps:
a substrate;
a bottom electrode pattern formed on said substrate;
a layer of phase change material pattern formed on said bottom electrode pattern;
a dielectric layer pattern formed on said layer of phase change material pattern;
a spacer structure formed between an opening of said dielectric layer pattern; and
a top electrode pattern disposed upon said dielectric layer pattern.

8. The method as claimed in claim 7, further comprising adding at least one adhesive layer, at least one heating layer, or at least one etching stop layer on any side of the layer of phase change material pattern.

9. The method as claimed in claim 7, wherein the layer of phase change material pattern is a horizontal film.

10. The method as claimed in claim 7, wherein the layer of phase change material pattern and the top electrode pattern in the via part form an inverted T-shape structure.

11. A structure for improving the characteristics of phase change memory, comprising the following steps:
a substrate;
a bottom electrode pattern formed on said substrate;
a layer of phase change material pattern formed on said bottom electrode pattern;
a dielectric layer pattern formed on said layer of phase change material pattern;
at least one adhesive layer on formed any side of said layer of phase change material pattern;
a spacer structure formed between an opening of said dielectric layer pattern; and
a top electrode pattern disposed upon said dielectric layer pattern.

12. The method as claimed in claim 11, wherein the at least one adhesive layer has at least one heating layer or at least one etching stop layer.

13. The method as claimed in claim 11, wherein the layer of phase change material pattern is a horizontal film.

14. The method as claimed in claim 11, wherein the layer of phase change material pattern and a hole part of the top electrode pattern forms an inverted T-shape.
